(19) United States
(12) Patent Application Publication
(10) Pub. No.: US 2012/0205672 A1
(43) Pub. Date: Aug. 16, 2012

(54) SEMICONDUCTOR CHIP MODULE AND SEMICONDUCTOR PACAKGE HAVING THE SAME

(75) Inventors: Hyun Chul SEO, Icheon-si (KR); Seung Yeop LEE, Seoul (KR)

(73) Assignee: HYNIX SEMICONDUCTOR INC., Icheon-si (KR)

(21) Appl. No.: 13/360,011

(22) Filed: Jan. 27, 2012

(30) Foreign Application Priority Data
Feb. 15, 2011 (KR) 10-2011-0013230

(51) Int. Cl. H01L 33/08

(52) U.S. Cl. 257/84; 257/E33.066

(57) ABSTRACT

A semiconductor chip module includes a first semiconductor chip possessing a first surface and a second surface which faces away from the first surface, and having a first transmission and reception unit which includes at least two light emitting sections and at least two light receiving sections arranged in a form of a matrix on the first surface and configured to transmit and receive optical signals; and a second semiconductor chip disposed over the first surface of the first semiconductor chip, and having a second transmission and reception unit which includes at least two light emitting sections and at least two light receiving sections arranged in a form of a matrix on a surface of the second semiconductor chip facing the first semiconductor chip and configured to transmit and receive optical signals.

### CROSS-REFERENCE TO RELATED APPLICATIONS

The present application claims priority to Korean patent application number 10-2011-0013230 filed on Feb. 15, 2011, which is incorporated herein by reference in its entirety.

### BACKGROUND OF THE INVENTION

The present invention relates to a semiconductor package, and more particularly, to a semiconductor chip module which can enable transmission of various signals through an optical interface scheme, thereby improving electrical characteristics, and a semiconductor package having the same.

Most semiconductor packages use connection members formed of a metallic substance as a means for mounting a semiconductor chip to a printed circuit board (PCB). Typically in a semiconductor package, a connection scheme is used in which a printed circuit board and a semiconductor chip mounted to the printed circuit board are electrically connected with each other by connection members such as metal wires, metal bumps or through-silicon vias made of a metallic substance.

In the conventional art in which metallic connection members are used advantages are provided in that it is easy to perform a manufacturing process and reliability is excellent. Disadvantages of using metallic connection members are caused in that, since transmission of electrical signals between a printed circuit board and a semiconductor chip is implemented through connection members made of a metallic substance, electrical characteristics are likely to suffer signal distortion or noise when transmitting a signal.

For example, in the conventional case in which a printed circuit board and a semiconductor chip are electrically connected using metal wires as connection members, since exchange of electrical signals is implemented through metal wires, a signal transmission speed becomes slow, a speed difference is caused between metal wires with different lengths, and when a number of metal wires are used, the electrical characteristics of each semiconductor package is likely to degrade.

Moreover, in the conventional case in which a printed circuit board and a semiconductor chip are electrically connected using metal bumps as connection members, a defect such as a crack is likely to occur in joint regions where the semiconductor chip and the printed circuit board are connected. These cracks may be caused by differences in a thermal expansion coefficient among the substances of the metal bumps, the semiconductor chip and the printed circuit board. Thus, the reliability of the joint regions may deteriorate.

Further, in the conventional case in which a printed circuit board and a semiconductor chip are electrically connected using through-silicon vias made of a metallic substance, since a junction area between each through-silicon via and an underlying metal line is small, if a fail occurs in even one of a number of junctions, an entire semiconductor package may be sorted as a bad product. Further there may be a difference between electrical signals due to a difference between junction areas of the respective junctions.

As a consequence, in the conventional semiconductor package in which connection members such as metal wires, bumps and vias are used, various limitations exist as the technologies and performances of a semiconductor chip and a semiconductor package trend toward a high speed operation. Thus, a semiconductor package capable of improving a signal transmission speed between a semiconductor chip and a printed circuit board and improving electrical reliability is needed in the art.

### BRIEF SUMMARY OF THE INVENTION

Embodiments of the present invention are directed to a semiconductor chip module and a semiconductor package which can enable transmission of various signals through an optical interface scheme.

Embodiments of the present invention are also directed to a semiconductor chip module and a semiconductor package which can improve electrical characteristics through transmission of various signals.

In one embodiment of the present invention, a semiconductor chip module includes: a first semiconductor chip possessing a first surface and a second surface which faces away from the first surface, and having a first transmission and reception unit which includes at least two light emitting sections and at least two light receiving sections arranged in a form of a matrix on the first surface and configured to transmit and receive optical signals; and a second semiconductor chip disposed over the first surface of the first semiconductor chip, and having a second transmission and reception unit which includes at least two light emitting sections and at least two light receiving sections arranged in a form of a matrix on a surface of the second semiconductor chip facing the first semiconductor chip and configured to transmit and receive optical signals.

The first transmission and reception unit and the second transmission and reception unit may have a same surface area.

Each of the light emitting sections and light receiving sections of the first and second transmission and reception units may have a square or rectangular shape.

The light emitting sections and the light receiving sections of each of the first and second transmission and reception units may be alternately arranged.

The light emitting sections and the light receiving sections of each of the first and second transmission and reception units may be disposed to define groups.

The semiconductor chip module may further include:

first pads formed on the first surface of the first semiconductor chip and electrically connecting the first semiconductor chip and the first transmission and reception unit with each other; and second pads formed on the surface of the second semiconductor chip facing the first semiconductor chip and electrically connecting the second semiconductor chip and the second transmission and reception unit with each other.

The semiconductor chip module may further include adhesives respectively interposed between the first semiconductor chip and the first transmission and reception unit and between the second semiconductor chip and the second transmission and reception unit.

In another embodiment of the present invention, a semiconductor package includes: a substrate possessing a first surface and a second surface which faces away from the first surface, and having a first transmission and reception unit which includes at least two light emitting sections and at least two light receiving sections arranged in a form of a matrix on the first surface and configured to transmit and receive optical signals; and a semiconductor chip mounted to the first surface of the substrate, and having a second transmission and reception unit which includes at least two light emitting sections and at least two light receiving sections arranged in a form of a matrix on a surface of the semiconductor chip facing the substrate and configured to transmit and receive optical signals.

The first transmission and reception unit and the second transmission and reception unit may have a same surface area.

Each of the light emitting sections and light receiving sections of the first and second transmission and reception units may have a square or rectangular shape.

The light emitting sections and the light receiving sections of each of the first and second transmission and reception units may be alternately arranged.

The light emitting sections and the light receiving sections of each of the first and second transmission and reception units may be disposed to define groups.

The semiconductor package may further include: first pads formed on the first surface of the substrate and electrically connecting the substrate and the first transmission and reception unit with each other; and second pads formed on the surface of the semiconductor chip facing the substrate and electrically connecting the semiconductor chip and the second transmission and reception unit with each other.

The semiconductor package may further include adhesives respectively interposed between the substrate and the first transmission and reception unit and between the semiconductor chip and the second transmission and reception unit.

In another embodiment of the present invention, a semiconductor package includes: a first package including a first substrate and a first semiconductor chip mounted to the first substrate, and having a first transmission and reception unit which includes at least two light emitting sections and at least two light receiving sections arranged in a form of a matrix on an upper surface of the first semiconductor chip and configured to transmit and receive optical signals; and a second package disposed over the first package, including a second substrate and a second semiconductor chip mounted to the second substrate, and having a second transmission and reception unit which includes at least two light emitting sections and at least two light receiving sections arranged in a form of a matrix on a lower surface of the second substrate facing the first package and configured to transmit and receive optical signals.

The first transmission and reception unit and the second transmission and reception unit may have a same surface area.

Each of the light emitting sections and light receiving sections of the first and second transmission and reception units may have a square or rectangular shape.

The light emitting sections and the light receiving sections of each of the first and second transmission and reception units may be alternately arranged.

The light emitting sections and the light receiving sections of each of the first and second transmission and reception units may be disposed to define groups.

The semiconductor package may further include: first pads formed on the upper surface of the first semiconductor chip and electrically connecting the first semiconductor chip and the first transmission and reception unit with each other; and second pads formed on the lower surface of the second substrate and electrically connecting the second substrate and the second transmission and reception unit with each other.

The semiconductor package may further include adhesives respectively interposed between the first semiconductor chip and the first transmission and reception unit and between the second substrate and the second transmission and reception unit.

### BRIEF DESCRIPTION OF THE DRAWINGS

FIG. 1 is a cross-sectional view illustrating a semiconductor chip module in accordance with an embodiment of the present invention.

FIG. 2 is a plan view for explaining a transmission and reception unit in accordance with an embodiment of the present invention.

FIGS. 3A and 3B are plan views illustrating transmission and reception units in accordance with an embodiment of the present invention.

FIGS. 4 and 5 are cross-sectional views illustrating semiconductor packages in accordance with other embodiments of the present invention.

FIGS. 6 and 7 are cross-sectional views illustrating semiconductor packages in accordance with still other embodiments of the present invention.

### DESCRIPTION OF SPECIFIC EMBODIMENTS

Hereafter, specific embodiments of the present invention will be described in detail with reference to the accompanying drawings.

It is to be understood herein that the drawings are not necessarily to scale and in some instances proportions may have been exaggerated in order to more clearly depict certain features of embodiments of the invention.

FIG. 1 is a cross-sectional view illustrating a semiconductor chip module in accordance with an embodiment of the present invention.

Referring to FIG. 1, a first semiconductor chip 110 having first surface and a second surface facing away from the first surface is prepared, and a first transmission and reception unit 200 is disposed on the first surface of the first semiconductor chip 110. First pads 112, which are electrically connected with the first semiconductor chip 110, are formed on the first surface of the first semiconductor chip 110. The first pads 112 electrically connect the first semiconductor chip 110 and the first transmission and reception unit 200 with each other. An adhesive 130 is formed between the first transmission and reception unit 200 and the first semiconductor chip 110.

The first transmission and reception unit 200 functions to transmit and/or receive an optical signal. In detail, the first transmission and reception unit 200 includes at least two light emitting sections and at least two light receiving sections which are arranged in the form of a matrix, and functions to generate optical signals and transmit the optical signals through the light emitting sections or receive the optical signals transmitted from a second transmission and reception unit 300 through the sensors included in the light receiving sections. The first transmission and reception unit 200 may be constituted by a plurality of sensors or may be constituted by a single sensor so long as the sensor can receive optical signals generated from the second transmission and reception unit 300.

A second semiconductor chip 120 is disposed over the first surface of the first semiconductor chip 110. The second semiconductor chip 120 has the second transmission and reception unit 300 for transmitting and receiving optical signals, on the surface thereof facing the first semiconductor chip 110. The second transmission and reception unit 300 includes at least two light emitting sections and at least two light receiving sections which are arranged in the form of a matrix. Second pads 122, which are electrically connected with the second semiconductor chip 120, are formed on a surface of the second semiconductor chip 120 facing the first semiconductor chip 110. The second pads 122 electrically connect the second semiconductor chip 120 and the second transmission and reception unit 300 with each other. An adhesive 130 is formed between the second transmission and reception unit 300 and the second semiconductor chip 120.

The first transmission and reception unit 200 provided to the first semiconductor chip 110 and the second transmission and reception unit 300 provided to the second semiconductor chip 120 may or may not have the surface same area. For example, the first transmission and reception unit 200 may not have the same area as the second transmission and reception unit 300 so long as the first transmission and reception unit 200 can receive/send optical signals transmitted/received to/from the second transmission and reception unit 300. That is to say, while not depicted, the first transmission and reception unit 200 and the second transmission and reception unit 300 may have different areas surface areas and/or volumes.

Also, the first transmission and reception unit 200 provided to the first semiconductor chip 110 and the second transmission and reception unit 300 provided to the second semiconductor chip 120 may be disposed to be brought into contact with each other or may be disposed to be separated from each other by a distance at which transfer of optical signals may be smoothly implemented between the second transmission and reception unit 300 and the first transmission and reception unit 200. When the second transmission and reception unit 300 and the first transmission and reception unit 200 are disposed to be separated from each other, spacers (not shown) may be disposed between the first and second semiconductor chips 110 and 120 such that a distance between the second transmission and reception unit 300 and the first transmission and reception unit 200 can be maintained.

In an embodiment of the present invention described above, an optical interface scheme for generating and transmitting optical signals or receiving optical signals through sensors is adopted for signal transfer between the first semiconductor chip 110 and the second semiconductor chip 120. Consequently, in an embodiment of the present invention, electrical connection and signal transfer between the first semiconductor chip 110 and the second semiconductor chip 120 become possible without the use of connection members made of a metallic substance.

Accordingly, in an embodiment of the present invention, when transferring signals between the first semiconductor chip 110 and the second semiconductor chip 120, influences by signal distortion or noise generation due to the use of the connection members made of a metallic substance may be reduced, whereby a signal transfer speed can be improved. Further, in an embodiment of the present invention, it is possible to avoid failures such as a crack or a poor junction, which otherwise occurs at joint regions between connection members made of a metallic substance. Therefore, the electrical reliability of a semiconductor chip module can be improved.

In particular, in the above-described embodiment of the present invention, because each of the first and second transmission and reception units 200 and 300 includes at least two light emitting sections and at least two light receiving sections which are arranged in the form of a matrix, various optical signals may be generated through the at least two light emitting sections. As a consequence, in an embodiment of the present invention, transfer of various signals between the second transmission and reception unit 300 and the first transmission and reception unit 200 becomes possible, whereby the electrical characteristics of the semiconductor chip module can be effectively improved.

Although not depicted, the first transmission and reception unit 200 and the second transmission and reception unit 300 may be disposed to be inserted into the first semiconductor chip 110 and the second semiconductor chip 120. In this case, the entire height of the semiconductor chip module, in which the first semiconductor chip 110 and the second semiconductor chip 120 are stacked, may be decreased.

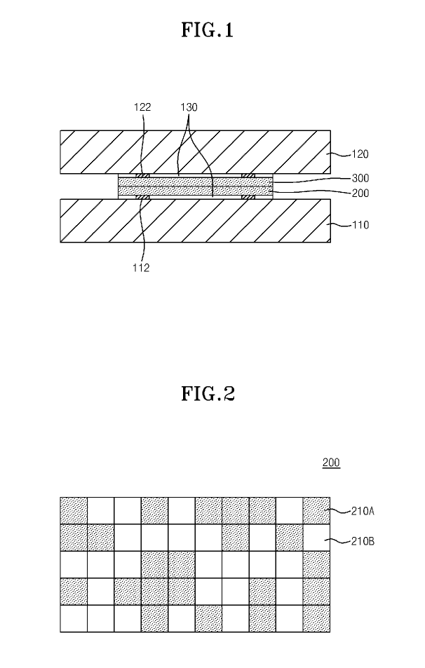

FIG. 2 is a plan view for explaining in detail the transmission and reception unit in accordance with an embodiment of the present invention. Since the first transmission and reception unit 200 and the second transmission and reception unit 300 described above may have the same structure, only the first transmission and reception unit 200 will be illustrated and described herein.

Referring to FIG. 2, the first transmission and reception unit 200 in accordance with an embodiment of the present invention includes light emitting sections 210A for emitting optical signals and light receiving sections 210B for receiving optical signals. In particular in an embodiment, the first transmission and reception unit 200 is characterized in that at least two light emitting sections 210A and at least two light receiving sections 210B are arranged in the form of a matrix. Each of the light emitting sections 210A of the first transmission and reception unit 200 may have a square or a rectangular shape. Meanwhile, although not depicted, each of the light emitting sections 210A or the light receiving sections 210B may have a shape different from the square or rectangular shape.

The first transmission and reception unit 200 including the light emitting sections 210A and the light receiving sections 210B are formed on a semiconductor chip or a substrate in such a way as to be electrically connected with the semiconductor chip or the substrate. The light emitting sections 210A emit light when a predetermined voltage is applied to any one of the semiconductor chip and the substrate, for example, when the predetermined voltage is applied to the semiconductor chip. That is to say, each of the light emitting sections 210A is indicated as being turned on by emitting light or is indicated as being turned off by not emitting light.

As the respective light emitting sections 210A are indicated as being turned on or off in this way, the first transmission and reception unit 200 represents specified patterns. In detail, as the respective light emitting sections 210A are indicated as being turned on or off, the first transmission and reception unit 200 in which the light emitting sections 210A are disposed in the form of a matrix may represent specified patterns. As these patterns are presented as optical signals, the optical signals are transmitted from the first transmission and reception unit 200. For example, in the case where the first transmission and reception unit 200 includes n number of light emitting sections 210A which are arranged in the form of a matrix, the first transmission and reception unit 200 may generate and transmit 2ⁿ number of different optical signals.

In other words, in the embodiment of the present invention, the first transmission and reception unit 200 at least two light emitting sections 210A which are arranged in the form of a matrix, and the respective light emitting sections 210A are indicated as being turned on or off by emitting light or not emitting light. The first transmission and reception unit 200 may represent specified patterns through an indication scheme of respective light emitting sections 210A being turned on or off, and in this way the light emitting sections 210A may generate a plurality of different optical signals.

Therefore, in an embodiment of the present invention, because the first transmission and reception unit 200 for transmitting optical signals includes at least two light emitting sections 210A, when the first transmission and reception unit 200 includes a plurality of light emitting sections 210A, for example, n number of light emitting sections 210A, it is possible to generate 2ⁿ number of optical signals from the first transmission and reception unit 200. Hence, in an embodiment of the present invention, it is possible to transmit various optical signals from a semiconductor chip or a substrate which has the first transmission and reception unit 200. As a consequence, in an embodiment of the present invention, an optical interface scheme capable of transferring various optical signals is adopted, whereby the electrical characteristics of a semiconductor chip module or a semiconductor package can be improved.

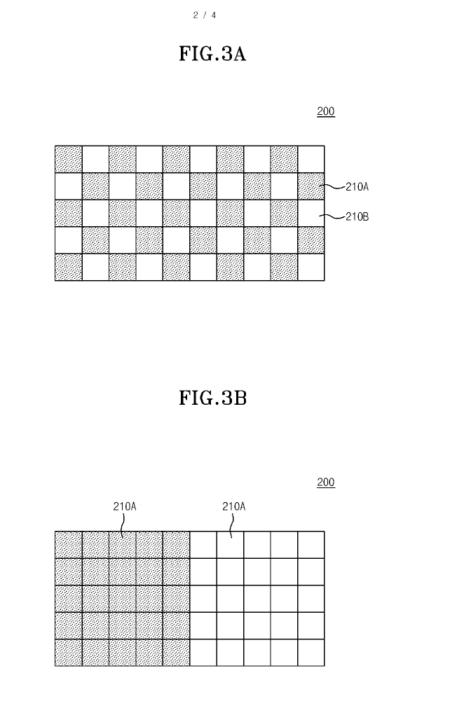

FIGS. 3A and 3B are plan views for explaining a state in which the light emitting section and the light receiving section of the transmission and reception unit are disposed in accordance with an embodiment of the present invention.

Referring to FIG. 3A, the first transmission and reception unit 200 includes a plurality of light emitting sections 210A and a plurality of light receiving sections 210B. The light emitting sections 210A and the light receiving sections 210B are arranged alternately with each other.

Referring to FIG. 3B, the first transmission and reception unit 200 includes a plurality of light emitting sections 210A and a plurality of light receiving sections 210B. The light emitting sections 210A and the light receiving sections 210B are arranged into groups, and respective groups are disposed independently of each other.

While not depicted, the light emitting sections and the light receiving sections may be arranged along rows or columns such that the light emitting sections and the light receiving sections arranged along rows or columns are alternately separated from each other.

While it was illustrated and described in the above embodiment of the present invention that an optical interface scheme capable of transferring various optical signals is adopted for electrical connection and signal transfer between semiconductor chips, it is to be noted that the present invention is not limited to such. In another embodiment of the present invention, an optical interface scheme capable of transferring various optical signals may be adopted for electrical connection and signal transfer between a substrate and a semiconductor chip.

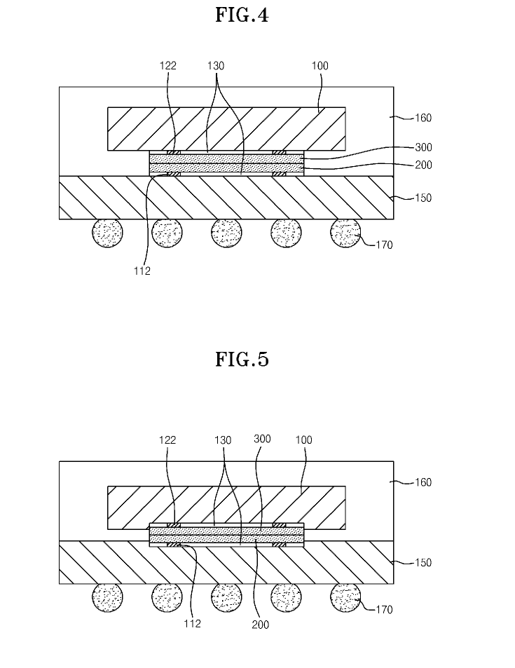

FIG. 4 is a cross-sectional view illustrating a semiconductor package in accordance with another embodiment of the present invention.

Referring to FIG. 4, a substrate 150 having a first surface and a second surface facing away from the first surface is prepared. A first transmission and reception unit 200 is disposed on the first surface of the substrate 150. First pads 112, which are electrically connected with the substrate 150, are formed on the first surface of the substrate 150. The first pads 112 electrically connect the substrate 150 and the first transmission and reception unit 200 with each other. An adhesive 130 is formed between the first transmission and reception unit 200 and the substrate 150.

The first transmission and reception unit 200 functions to transmit and/or receive an optical signal. In detail, the first transmission and reception unit 200 includes at least two light emitting sections and at least two light receiving sections which are arranged in the form of a matrix, and functions to generate optical signals and transmit the optical signals through the light emitting sections or receive the optical signals transmitted from a second transmission and reception unit 300 through sensors included in the light receiving sections. The first transmission and reception unit 200 may be constituted by a plurality of sensors or may be constituted by a single sensor so long as the sensor can receive the optical signals generated from the second transmission and reception unit 300.

A semiconductor chip 100 is mounted over the first surface of the substrate 150. The semiconductor chip 100 may be disposed over the first surface of the substrate 150 with an adhesive (not shown) interposed therebetween. The semiconductor chip 100 has the second transmission and reception unit 300 for transmitting or receiving optical signals, on the surface of the second transmission and reception unit 300 facing the substrate 150. As shown in FIG. 2, the second transmission and reception unit 300 includes at least two light emitting sections 210A and at least two light receiving sections 210B which are arranged in the form of a matrix. Second pads 122, which are electrically connected with the semiconductor chip 100, are formed on the surface of the semiconductor chip 100 facing the substrate 150. The second pads 122 electrically connect the semiconductor chip 100 and the second transmission and reception unit 300 with each other. An adhesive 130 is formed between the second transmission and reception unit 300 and the semiconductor chip 100.

The first transmission and reception unit 200 provided to the substrate 150 and the second transmission and reception unit 300 provided to the semiconductor chip 100 may or may not have a same surface area. The first transmission and reception unit 200 may have a different surface area from the second transmission and reception unit 300 so long as the first transmission and reception unit 200 can receive optical signals transmitted from the second transmission and reception unit 300. That is to say, while not depicted, the first transmission and reception unit 200 and the second transmission and reception unit 300 may have different surface areas and/or volumes. Each of the light emitting sections 210A and the light receiving sections 210B of the second transmission and reception unit 300 may have a square or a rectangular shape as shown in FIG. 2. When the second transmission and reception unit 300 includes n number of light emitting sections 210A, the second transmission and reception unit 300 may generate 2ⁿ number of different optical signals.

The first transmission and reception unit 200 provided to the substrate 150 and the second transmission and reception unit 300 provided to the semiconductor chip 100 may be disposed to be brought into contact with each other or may be disposed to be separated from each other by a distance at which transfer of optical signals may be smoothly implemented between the second transmission and reception unit 300 and the first transmission and reception unit 200. When the second transmission and reception unit 300 and the second transmission and reception unit 200 are disposed to be separated from each other, spacers (not shown) may be disposed between the substrate 150 and the semiconductor chip 100 such that the distance between the second transmission and reception unit 300 and the first transmission and reception unit 200 can be maintained.

An encapsulation member 160 is formed to seal the first surface of the substrate 150 over which the semiconductor chip 100 is mounted. External connection terminals 170 are formed on the second surface of the substrate 150 facing away from the first surface.

In the another embodiment of the present invention described above, an optical interface scheme using the first transmission and reception unit 200 and the second transmission and reception unit 300 for transmitting and receiving optical signals is adopted for electrical connection and signal transfer between the substrate 150 and the semiconductor chip 100. Consequently, in the another embodiment of the present invention, without using connection members made of a metallic substance, electrical connection and signal transfer between the substrate 150 and the semiconductor chip 100 become possible. As a result, a signal transfer speed is improved, and a fail such as a crack or a poor junction is prevented from occurring, whereby the electrical reliability of a semiconductor package may be improved.

In particular, in the above-described embodiment of the present invention, due to the fact that each of the first and second transmission and reception units 200 and 300 includes at least two light emitting sections and at least two light receiving sections which are arranged in the form of a matrix, various optical signals may be generated through the at least two light emitting sections. As a consequence, in the embodiment of the present invention, transfer of various signals between the second transmission and reception unit 300 and the first transmission and reception unit 200 becomes possible, whereby the electrical characteristics of the semiconductor chip module can be effectively improved.

Also, as shown in FIG. 5, the first transmission and reception unit 200 and the second transmission and reception unit 300 may be disposed to be respectively inserted into the substrate 150 and the semiconductor chip 100, and in this case, the entire height of the semiconductor package, in which the substrate 150 and the semiconductor chip 100 are stacked, may be decreased.

Meanwhile, although it was illustrated and described in the above embodiment of the present invention that an optical interface scheme capable of transferring various optical signals is adopted for electrical connection and signal transfer between the substrate 150 and the semiconductor chip 100, it is to be noted that the present invention is not limited to such. In still another embodiment of the present invention, an optical interface scheme capable of transferring various optical signals may be adopted for electrical connection and signal transfer between packages in a POP (package on package) structure.

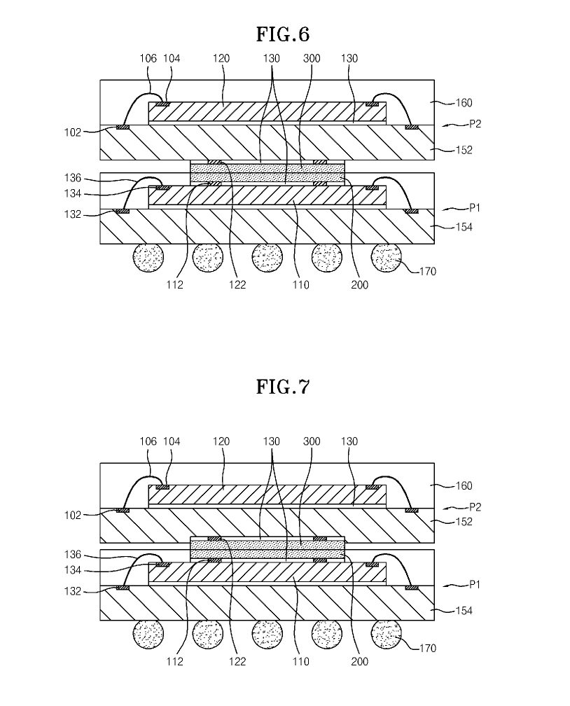

FIG. 6 is a cross-sectional view illustrating a semiconductor package in accordance with still another embodiment of the present invention.

Referring to FIG. 6, a first package P1 including a first substrate 154 and a first semiconductor chip 110 which is mounted to the first substrate 154 is prepared. The first substrate 154 and the first semiconductor chip 110 are electrically connected with each other, for example, through first bonding wires 136. The first bonding wires 136 electrically connect first bonding pads 134 of the first semiconductor chip 110 and first bond fingers 132 of the first substrate 154. An encapsulation member 160 is formed to seal a first surface of the first substrate 154 including the first semiconductor chip 110 mounted thereto, and external connection terminals 170 are formed on the second surface of the substrate 154 facing away from the first surface.

A first transmission and reception unit 200 is disposed on an upper surface of the first package P1, for example, on an upper surface of the first semiconductor chip 110. First pads 112, which are electrically connected with the first semiconductor chip 110, are formed on the upper surface of the first semiconductor chip 110. The first pads 112 electrically connect the first semiconductor chip 110 and the first transmission and reception unit 200 with each other. An adhesive 130 is formed between the first transmission and reception unit 200 and the first semiconductor chip 110.

The first transmission and reception unit 200 functions to transmit and/or receive an optical signal. In detail, the first transmission and reception unit 200 includes at least two light emitting sections and at least two light receiving sections which are arranged in the form of a matrix, and functions to generate optical signals and transmit the optical signals through the light emitting sections or receive optical signals transmitted from a second transmission and reception unit 300 through the sensors included in the light receiving sections. The first transmission and reception unit 200 may be constituted by a plurality of sensors or may be constituted by a single sensor so long as the sensor can receive the optical signals generated from the second transmission and reception unit 300.

A second package P2 including a second substrate 152 and a second semiconductor chip 120 which is mounted to the second substrate 152 is disposed over the first package P1. The second substrate 152 and the second semiconductor chip 120 are electrically connected with each other, for example, through second bonding wires 106. The second bonding wires 106 electrically connect second bonding pads 104 of the second semiconductor chip 120 and second bond fingers 102 of the second substrate 152 with each other. An encapsulation member 160 is formed to seal one surface of the second substrate 152 including the second semiconductor chip 120 mounted thereto.

The second package P2 has the second transmission and reception unit 300 for generating and transmitting optical signals and/or receiving optical signals generated from the first transmission and reception unit 200. The second transmission and reception unit 300 may be disposed on a surface of the second substrate 152 facing the first package P1, for example, on the lower surface of the second substrate 152 facing the first package P1. As shown in FIG. 2, the second transmission and reception unit 300 includes at least two light emitting sections 210A and at least two light receiving sections 210B which are arranged in the form of a matrix. Second pads 122, which are electrically connected with the second substrate 152, are formed on the lower surface of the second substrate 152 facing the first package P1. The second pads 122 electrically connect the second substrate 152 and the second transmission and reception unit 300 with each other. An adhesive 130 is formed between the second transmission and reception unit 300 and the second substrate 152.

The first transmission and reception unit 200 provided to the first package P1 and the second transmission and reception unit 300 provided to the second package P2 may have a same surface area and/or volume. On the other hand, the first transmission and reception unit 200 may have a different surface area or volume from the second transmission and reception unit 300 so long as it can receive the optical signals transmitted from the second transmission and reception unit 300. That is to say, although not depicted, the first transmission and reception unit 200 and the second transmission and reception unit 300 may have different areas. Each of the light emitting sections 210A and the light receiving sections 210B of the second transmission and reception unit 300 may have a square or a rectangular shape as shown in FIG. 2. When the second transmission and reception unit 300 includes n number of light emitting sections 210A which are arranged, the second transmission and reception unit 300 may generate 2ⁿ number of different optical signals.

The first transmission and reception unit 200 provided to the first package P1 and the second transmission and reception unit 300 provided to the second package P2 may be disposed to be brought into contact with each other or may be disposed to be separated from each other by a distance at which transfer of optical signals may be smoothly implemented between the second transmission and reception unit 300 and the first transmission and reception unit 200. When the second transmission and reception unit 300 and the first transmission and reception unit 200 are disposed to be separated from each other, spacers (not shown) may be disposed between the first package P1 and the second package P2 such that a distance between the second transmission and reception unit 300 and the first transmission and reception unit 200 can be maintained.

In the still another embodiment of the present invention described above, an optical interface scheme using the first transmission and reception unit 200 and the second transmission and reception unit 300 for transmitting and receiving optical signals is adopted for electrical connection and signal transfer between the packages P1 and P2 in a POP structure. Consequently, in an other embodiment of the present invention, without using connection members made of a metallic substance, electrical connection and signal transfer between the packages P1 and P2 becomes possible. As a result, a signal transfer speed is improved, and failures such as cracks or poor junctions are prevented from occurring, whereby the electrical reliability of a semiconductor package may be improved.

In particular, in the above-described embodiment of the present invention, because each of the first and second transmission and reception units 200 and 300 includes at least two light emitting sections and at least two light receiving sections which are arranged in the form of a matrix, various optical signals may be generated through the at least two light emitting sections. As a consequence, in an embodiment of the present invention, transfer of various signals between the second transmission and reception unit 300 and the first transmission and reception unit 200 becomes possible, whereby the electrical characteristics of the semiconductor chip module can be effectively improved.

Also, as shown in FIG. 7, the first transmission and reception unit 200 and the second transmission and reception unit 300 may be disposed to be respectively inserted into the first package P1 and the second package P2, and in this case, the entire height of the semiconductor package, in which the first and second packages P1 and P2 are stacked, may be decreased.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A semiconductor chip module comprising:
a first semiconductor chip possessing a first surface and a second surface which faces away from the first surface, and having a first transmission and reception unit which includes at least two light emitting sections and at least two light receiving sections arranged in a form of a matrix on the first surface and configured to transmit and receive optical signals; and
a second semiconductor chip disposed over the first surface of the first semiconductor chip, and having a second transmission and reception unit which includes at least two light emitting sections and at least two light receiving sections arranged in a form of a matrix on a surface of the second semiconductor chip facing the first semiconductor chip and configured to transmit and receive optical signals.

2. The semiconductor chip module according to claim 1, wherein the first transmission and reception unit and the second transmission and reception unit have a same surface area.

3. The semiconductor chip module according to claim 1, wherein each of the light emitting sections and light receiving sections of the first and second transmission and reception units has a square or rectangular shape.

4. The semiconductor chip module according to claim 1, wherein the light emitting sections and the light receiving sections of each of the first and second transmission and reception units are alternately arranged.

5. The semiconductor chip module according to claim 1, wherein the light emitting sections and the light receiving sections of each of the first and second transmission and reception units are disposed to define groups.

6. The semiconductor chip module according to claim 1, further comprising:
first pads formed on the first surface of the first semiconductor chip and electrically connecting the first semiconductor chip and the first transmission and reception unit with each other; and
second pads formed on the surface of the second semiconductor chip facing the first semiconductor chip and electrically connecting the second semiconductor chip and the second transmission and reception unit with each other.

7. The semiconductor chip module according to claim 1, further comprising:
adhesives respectively interposed between the first semiconductor chip and the first transmission and reception unit and between the second semiconductor chip and the second transmission and reception unit.

8. A semiconductor package comprising:
a substrate possessing a first surface and a second surface which faces away from the first surface, and having a first transmission and reception unit which includes at least two light emitting sections and at least two light receiving sections arranged in a form of a matrix on the first surface and configured to transmit and receive optical signals; and
a semiconductor chip mounted to the first surface of the substrate, and having a second transmission and reception unit which includes at least two light emitting sections and at least two light receiving sections arranged in a form of a matrix on a surface of the semiconductor chip facing the substrate and configured to transmit and receive optical signals.

9. The semiconductor package according to claim 8, wherein the first transmission and reception unit and the second transmission and reception unit have a same surface area.

10. The semiconductor package according to claim 8, wherein each of the light emitting sections and light receiving sections of the first and second transmission and reception units has a square or rectangular shape.

11. The semiconductor package according to claim 8, wherein the light emitting sections and the light receiving sections of each of the first and second transmission and reception units are alternately arranged.

12. The semiconductor package according to claim 8, wherein the light emitting sections and the light receiving sections of each of the first and second transmission and reception units are disposed to define groups.

13. The semiconductor package according to claim 8, further comprising:
first pads formed on the first surface of the substrate and electrically connecting the substrate and the first transmission and reception unit with each other; and
second pads formed on the surface of the semiconductor chip facing the substrate and electrically connecting the semiconductor chip and the second transmission and reception unit with each other.

14. The semiconductor package according to claim 8, further comprising:
adhesives respectively interposed between the substrate and the first transmission and reception unit and between the semiconductor chip and the second transmission and reception unit.

15. A semiconductor package comprising:
a first package including a first substrate and a first semiconductor chip mounted to the first substrate, and having a first transmission and reception unit which includes at least two light emitting sections and at least two light receiving sections arranged in a form of a matrix on an upper surface of the first semiconductor chip and configured to transmit and receive optical signals; and
a second package disposed over the first package, including a second substrate and a second semiconductor chip mounted to the second substrate, and having a second transmission and reception unit which includes at least two light emitting sections and at least two light receiving sections arranged in a form of a matrix on a lower surface of the second substrate facing the first package and configured to transmit and receive optical signals.

16. The semiconductor package according to claim 15, wherein the first transmission and reception unit and the second transmission and reception unit have a same surface area.

17. The semiconductor package according to claim 15, wherein each of the light emitting sections and light receiving sections of the first and second transmission and reception units has a square or rectangular shape.

18. The semiconductor package according to claim 15, wherein the light emitting sections and the light receiving sections of each of the first and second transmission and reception units are alternately arranged or disposed to define groups.

19. The semiconductor package according to claim 15, further comprising:
first pads formed on the upper surface of the first semiconductor chip and electrically connecting the first semiconductor chip and the first transmission and reception unit with each other; and
second pads formed on the lower surface of the second substrate and electrically connecting the second substrate and the second transmission and reception unit with each other.

20. The semiconductor package according to claim 15, further comprising:
adhesives respectively interposed between the first semiconductor chip and the first transmission and reception unit and between the second substrate and the second transmission and reception unit.
